(19) United States
(12) Patent Application Publication
(10) Pub. No.: US 2019/0048292 A1
(43) Pub. Date: Feb. 14, 2019

(54) Processing Composition of Improved Metal Interconnect Protection and The Use Thereof

(71) Applicants: Jiali Wu, Yorktown Heights, NY (US); Kellsie Shan, Carmel, NY (US); Lei Shan, Carmel, NY (US)

(72) Inventors: Jiali Wu, Yorktown Heights, NY (US); Kellsie Shan, Carmel, NY (US); Lei Shan, Carmel, NY (US)

(21) Appl. No.: 15/672,271

(22) Filed: Aug. 8, 2017

(51) Int. Cl. C11D 7/32; C11D 11/00; C11D 7/26; H01L 21/02

(52) U.S. Cl. CPC C11D 7/3209; C11D 11/0047; C11D 7/3218; H01L 23/53238; C11D 7/267; C11D 7/3245; H01L 21/02074; C11D 7/3281

(57) ABSTRACT

A semiconductor processing composition for removing residues and/or contaminants from substrate containing Cu, barrier metal and low-k dielectric. The processing composition includes at least one quaternary base, at least one organic amine, at least one surface modifier, at least one antioxidant, at least one complexing agent and balance water. The processing composition provides a sufficient corrosion protection to Cu and metal barrier during process queue time without deteriorating reliability of electronic devices.

### BACKGROUND

Cu-Low K technology dominates the mainstream of back end of line (BEOL) integration processes for semiconductor fabrication. BEOL processing scheme mainly consists of dielectric film deposition, litho patterning, trench and via etching, metal barrier deposition, Cu filling and chemical mechanical planarization (CMP), etc. unit processes. Through repeat of the aforementioned unit processes in sequence, low-K dielectric layers containing Cu interconnect are superimposed one after another. Critical dimensions of Cu interconnect, which used for the interconnection of isolated devices, are magnified incrementally thought out the Low K dielectric layers. Ultimately, Cu interconnects fulfill the function of connecting isolated nano-sized devices to the external power or signal transmitter.

Throughout BEOL processing flow, wafer surface cleaning post each unit process, especially for post-CMP, post-etch as well as resist removal, plays a detrimental role in terms of performance of electronic devices. Only residue-free and defect-free wafer surfaces could ensure a long-term reliabilities of electronic devices.

As semiconductor feature size further scale-down, RC latency becomes the foremost obstacle to the electronics performance. In order to meet the electric performance of ever-shrinking Cu interconnects with reducing pitch, Cu-Low K technology adopts tactics such as increasing dielectric material's porosity along with reducing metal barrier thickness and improving metal barrier coverage on trench and via sidewall. Accordingly, metal barrier is transferred from TaN, Ta, Ti, TiN to Co, Ru, W, Mo, Rh, Mn, etc. new transition metals, alloys and nitrides thereof. Metal barrier deposition process is accordingly changed from PVD to CVD. However, Cu interconnect dimensional shrinkage coupled with changing of dielectric porosity will pose tremendous challenges to the development of processing solutions for post-CMP cleaning, post-etch cleaning, as well as resist strip.

To inhibit copper oxidation during CMP process, polishing slurry usually contains anticorrosion additives, such as benzotriazole (BTA). However, if there is residue of anticorrosion additives remaining on the substrate surfaces, it will not only interfere with the bonding strength between the subsequent CVD dielectric layer and post-CMP substrate surface, but also cause an increase of Cu surface roughness which ultimately leads to early thermal and electrical failure during electric device reliability aging. However, completely removing of anticorrosion additive from substrate can introduce Cu and barrier metals corrosion during process queue time prior to the substrate entering into the next process step. Therefore, a competent surface modifier is able to prevent Cu and barrier metals from corrosion during process queue time, and then be removed during following CVD process to avoid bonding strength deterioration between interline dielectric layers.

For advanced electronic devices, atomic level Cu lose could cause electrical failure due to the ever shrinking critical dimension of Cu interconnects. Oxidation of Cu interconnects is equivalent to the Cu loss at atomic dimension. Therefore, it is imperative to control the oxygen level to a minimum by adding antioxidant in the cleaning solution.

The residues and/or contaminants carried on the surface of substrate post CMP are derived from slurry, cleaning brush, polishing pad, substances from planarized substrate, and other chemical reaction products. Besides removing residues and/or contaminants from substrate, it is important for post-CMP processing solution to possess a function of preventing removed residues and/or contaminants from descending to the surface of substrates.

In summary, as the critical dimension of the integrated circuit continuously scaling down along with applications of new metal barrier, post-CMP processing composition is called on to meet ever demanding standards including but not limited to post-CMP residues and/or contaminants removal, Cu and new barrier metal corrosion inhibition while maintaining porous dielectric K value and dielectric interlayer bonding strength.

### DETAILED DESCRIPTION OF THE INVENTION

The present invention relates to a semiconductor post-CMP processing composition for removing residues and/or contaminants from substrates containing copper interconnects. At the same time, the processing composition can provide sufficient corrosion protection to Cu interconnects and new barrier metals during process queue time, be compatible with Cu interline low-K dielectrics, especially have no adverse effects to the newly adopted copper diffusion barrier metals, such as cobalt (Co), ruthenium (Ru), tungsten (W), molybdenum (Mo), rhenium (Rh), manganese (Mn), alloys and nitrides thereof.

The “copper interconnect” as defined in the present invention refers to a metal interconnect for the connection of independent functional devices in the fields of microelectronics, flat panel displays, solar cells, microelectromechanical systems, and the like. It contains copper, or copper and its diffusion barrier metal.

The “low-k dielectric material” as defined in the present invention refers to an insulating material used as a dielectric between the integrated circuit of copper interconnects. The low-k dielectric material typically contains a high porosity structure with a dielectric constant of less than 4.0, preferably a dielectric constant of less than 2.4. Low-k dielectric materials include, but are not limited to, silicon oxide polymers, organosilicate glass, fluorosilicate glass, and carbon-doped silica glass.

The “new barrier metal” as defined in the present invention refers to metal cobalt (Co), ruthenium (Ru), tungsten (W), molybdenum (Mo), rhenium (Rh), Manganese (Mn), and alloys and nitrides thereof. The diffusion rate of copper in these metal is so small that they can be used as a barrier to prevent cupper diffuse into low-k dielectrics. In addition, Cu has good wettability on (Ru), cobalt (Co), tungsten (W), molybdenum (Mo), rhenium (Rh), manganese (Mn), and alloys and nitrides thereof. During 22 nm and smaller technology node BEOL integrate circuit fabrication, copper can be directly electroplated onto barrier metal without the need of a separate process step for copper seed layer vapor deposition, which greatly simplify the entire integrated circuit fabrication processes.

The term “residue” as defined in the present invention refers to the particulates remaining on the substrate surfaces carried out from CMP, etching, or wet etching processes during integrated circuit fabrication. Post-CMP residues include SiO₂, Al₂O₃ particles from slurry, debrides from polishing pad and brush, Cu/dielectric/barrier metal particulates from ground substrate. Residues derived from plasma asking or etching includes polymeric or metal byproducts due to plasma reactions between high energy plasma and photo mask, bottom reflective polymer, low K dielectric, or metal interconnect.

The term “contaminant” as defined herein refers to chemical substances remained on Cu interconnect containing substrates, which generated during CMP, etching, or wet etching processes for integrated circuit fabrication, such as organic additives or chemical reaction byproducts from CMP slurry or etching chemicals.

The present invention provides a processing composition for post-CMP cleaning, comprising at least one quaternary ammonium, at least one organic amine, at least one surface modifier, at least one antioxidant, at least one complexing agent and balance water. The processing composition is substantially devoid of any other chemical species, metal salts or metal ions other than those aforementioned. The processing solution provides sufficient corrosion protection to copper interconnects and copper diffusion barrier metals during process queue time prior to the substrate entering into next process step. At the same time, the processing composition will not deteriorate interface bonding strength between interline dielectric layers. The new copper diffusion barrier metal is selected from but not limited to ruthenium (Ru), cobalt (Co), tungsten (W), molybdenum (Mo), rhenium (Rh), manganese (Mn), tungsten (W), and alloys and nitrides thereof. Preferably, the diffusion barrier metal is Co, Ru, W. The processing composition does not impose adverse effect to the physical properties of the low-k dielectrics and retains their dielectric constant not change. Low-K dielectrics include, but are not limited to, organosilicate glass, fluorosilicate glass, carbon-doped silica glass, silica composites with high porosity, wherein their dielectric constant is typically less than 4.0, preferably equivalent to or less than 2.4. The processing composition of the present invention can be applied to, but not limited to, post-CMP cleaning, post-etch cleaning, or photoresist strip of substrates during integrated circuit fabrication.

The “substantially devoid” used in the present invention is defined as less than 0.01% by weight, preferably less than 0.001% by weight, more preferably less than 0.0001%, and most preferably less than 0% by weight processing composition.

Quaternary bases contemplated herein are selected from, but not limited to, tetraalkylammonium hydroxide, trialkyl-hydroxyalkylammonium hydroxide, dialkyl-bis(hydroxyalkyl) ammonium hydroxides and alkyl-tris (hydroxyalkyl) ammonium hydroxide, wherein the alkyl group contains straight or branch-chained C1 to C12 atoms or a combination of straight or branch-chained C1 to C12 atoms including tetrahexyl ammonium hydroxide (TEAH), tetramethylammonium hydroxide (TMAH), Tetrapropylammonium hydroxide (TPAH), tetrabutylammonium hydroxide (TBAH), tetraethylammonium hydroxide (TEAH), trimethylphenylammonium hydroxide (TMPAH), benzyltrimethylammonium hydroxide BTMAH), benzyl his (2-hydroxyethyl) methyl ammonium hydroxide, tributylmethylammonium hydroxide (TBMAH), ammonium hydroxide, tetrabutylphosphonium hydroxide (TBPH), tetrabutylphosphonium hydroxide, (2-hydroxyethyl) trimethyl ammonium hydroxide, tris (2-hydroxyethyl) methyl ammonium hydroxide, (2-hydroxyethyl) triethylammonium hydroxide, (2-hydroxyethyl) Propyl ammonium hydroxide, trimethyl-3-hydroxybutylammonium hydroxide, trimethyl-4-hydroxybutylammonium hydroxide, ethyltrimethylammonium hydroxide, diethyl dimethyl ammonium hydroxide, trifluoromethyl base) Phenyltrimethylammonium hydroxide and combinations thereof. Preferred quaternary ammoniums include tetramethylammonium hydroxide (TMAH), (2-hydroxyethyl) trimethylammonium hydroxide. The amount of quaternary base is in the range of about 0.001 wt % to 25 wt %, preferably from about 0.01 wt % to 15 wt % based on the total weight of the disclosed processing composition.

Organic amines contemplated herein are selected from, but not limited to, monoethanolamine, aminoethylethanolamine, N-methylaminoethanol, aminoethoxyethanol, diethanolamine, triethanolamine, 1-amino-2-propanol, 2-amino-1-butanol, isobutanolamine, tetraethylenepentamine, N,N,N′-trimethyl-N′-(2-hydroxyethyl) ethylenediamine, N,N-dimethyl Ethylethylenediamine, N,N′-dimethylethanolamine, isobutanolamine, isopropanolamine, 2-(diethylamino) ethanol, aminoethylethanolamine, N-methylaminoethanol, aminoethoxy Ethyl alcohol, dimethylaminoethoxyethanol, diethanolamine, N-methyldiethanolamine, monoethanolamine, triethanolamine, 1-amino-2-propanol, 2-amino-1-butanol, isobutanolamine, Triethylenediamine, C2-C12 direct or branched alkanolamines, and combinations thereof. Preferred organic amines include monoethanolamine. The amount of organic amine is from about 0.001% to 20% by weight, preferably from about 0.01% to 10% by weight, based on the total weight of the disclosed cleaning composition.

Surface modifiers are used to replace the residues and/or contaminants remaining on the surface of the substrate, such as BTA derived from CMP slurry, while providing corrosion protection of copper interconnect. Surface modifiers applied to the present invention are selected from, but not limited to, 1,2,3-triazole, 1,2,4-triazole, 3-amino-5-mercapto-1,2,4-triazole, Amino-1,2,4-triazole, hydroxybenzotriazole, 1-amino-5-methyl-1,2,3-triazole, 3-Amino-1,2,4-triazole, triazole, 3-isopropyl-1,2,4-triazole, 5-phenylthiol-benzotriazole, 2-mercaptobenzimidazole, 5-Methyl-2-phenylimidazole, 5-aminotetrazole, 5-amino-1,3,4-thiadiazole-2-thiol, thiazole, methyltetrazole, 1,5-pentamethylene 6-thiadiazole-2-thiol, benzothiazole, imidazole, indazole and combinations thereof; and N-ribosyl purine, purine, guanine, Purine, xanthine, isoguanine and methylated or deoxygenated derivatives; N-methyladenosine, N,N-dimethyladenosine, adenosine, 2-methoxyadenosine, 2-aminopurine nucleoside, trimethyladenosine and combinations thereof; pyrazole, pyrazole derivatives and combination thereof; pyrrole, pyrrole derivatives and combinations thereof. Preferred surface modifiers include 1,2,4-triazole, 1,2,3-triazole, imidazole, pyrrole, pyrazole. The amount of surface modifier is from about 0.001% to 12% by weight, preferably from about 0.01% to 8% by weight based on the total weight of the cleaning composition.

The effect of the antioxidant is to minimize the amount of oxidant in the cleaning composition, such as oxygen dissolved in the cleaning composition. The antioxidants of the present invention are selected from, but not limited to, ascorbic acid (vitamin C), L(+)-ascorbic acid, isoascorbic acid, ascorbic acid derivatives, uric acid, uric acid derivatives and combinations thereof. Preferred antioxidants include ascorbic acid. The amount of antioxidant is from about 0.001% to 10% by weight, preferably from about 0.001% to 6% by weight, based on the total weight of the disclosed cleaning composition.

A complexing agent is used for chemically bonding or physically combinding with transnational metals or metal ions. In post-CMP cleaning application, a complexing agent will facilitate CuO removal from Cu surface and prevent Cu and barrier metal from corrosion. The complexing agents of the present invention are selected from, but not limited to, citric acid, tartaric acid, oxalic acid, tributyl phosphate, dibutyl phosphate, ethylenediaminetetraacetic acid (EDTA), nitrilotriacetic acid, ethyl ethylenediamine triacetic acid (HEDTA), lactic acid, leucine, lysine, maleic acid, maleic anhydride, malic acid, malonic acid, mandelic acid, 2,4-pentanedione, phenylacetic acid, phenylalanine, Dicarboxylic acid, proline, CDTA, HIDA and N-AEP, 1-methoxy-2-aminoethane, tetraethylenepentamine (TEPA), gluconic acid, tartaric acid, dimethylethylene dioxime, Glutamic acid, glutamine, glutaric acid, glycerol, glycerol, glycolic acid, glyoxylic acid, histidine, iminodiacetic acid, isophthalic acid, coke catechol, 1,2,4, Trimellitic acid, quinic acid, serine, sorbitol, succinic acid, terephthalic acid, trimellitic acid, trimellitic acid and combinations thereof. Preferred complexing agent include ethyl ethylenediamine triacetic acid, nitrilotriacetic acid. The amount of the complexing agent is from about 0.0001% to 8% by weight, preferably from about 0.0001% to 4% by weight, based on the total weight of the disclosed processing composition.

Contact angle is a commonly used method for characterizing the surface wettability of substrate. The present invention uses surface contact angle technique to detect hydrophilicity degree of substrate related to the surface modification with organic adsorption. The adsorption of benzotriazole derived from slurry can cause poor surface wettability of substrate, which results in the increase of contact angle of polar deionized water on the substrate. The processing composition of the invention will partially or completely replace the benzotriazole during the cleaning process and reduce contact angle of deionized water due to the improvement of substrate hydrophilicity. The present invention utilizes DropMaster DM-701 goniometer to characterize the degree of surface modification of substrate containing Cu interconnect.

Preferred processing compositions for characterizing the hydrophilicity degree of the substrate are, Sample A compromises 0.01 wt % to 15 wt % tetramethylammonium hydroxide, 0.01 wt % to 10 wt % monoethanolamine, 0.01 wt % to 8 wt % 1,2,4-triazole, 0.001 wt % to 6 wt % ascorbic acid, 0.0001 wt % to 4 wt % (hydroxyethyl) ethylenediamine triacetic acid (HEDTA), and balance water; Sample B comprises 0.01 wt % to 15 wt % (2-hydroxyethyl) trimethylammonium hydroxide, 0.01 wt % to 10 wt % monoethanolamine, 0.01 wt % to 8 wt % 1,2,4-triazole, 0.001 wt % to 6 wt % ascorbic acid, 0.0001 wt % to 4 wt % nitrilotriacetic acid and balance water; Sample C compromises 0.01 wt % to 15 wt % tetramethylammonium hydroxide, 0.01 wt % to 10 wt % monoethanolamine, 0.01 wt % to 8 wt % pyrrole, 0.001 wt % to 6 wt % ascorbic acid, 0.0001 wt % to 4 wt % nitrilotriacetic acid and balance water; Sample D comprises 0.01 wt % to 12 wt % tetramethylammonium hydroxide, 0.01 wt % to 10 wt % monoethanolamine, 0.01 wt % to 7 wt % imidazole, 0.001 wt % to 5 wt % ascorbic acid, 0.0001 wt % to 4 wt % (Hydroxyethyl)ethylenediamine triacetic acid (HEDTA) and balance water; Sample E compromises 0.01 wt % to 13 wt % (2-hydroxyethyl) trimethylammonium hydroxide, 0.01 wt % to 10 wt % monoethanolamine, 0.01 wt % to 5 wt % Pyrazole, 0.001 wt % to 4 wt % ascorbic acid, 0.0001 wt % to 4 wt % (hydroxyethyl)ethylenediamine triacetic acid (HEDTA) and balance water.

Contact angles are measured using deionized water droplet stabilizing on substrate surface at a temperature of 15-20° C. for 60 seconds. Experiment step 1: silicon substrates with CVD Cu deposit were prepared for test. The samples were first immersed in 0.01M benzotriazole (BTA) aqueous solution at room temperature for 1 minute followed by 30 seconds rinsing with sample A, B, or C, respectively. Next the samples were rinsed with deionized water for 30 seconds followed by drying at atmosphere. Contact angles of deionized water droplet on the substrate of the samples were measured in 5 hours later. A BTA treated sample without rinsing of the processing compositions were used as a reference. Experiment Step 2: Samples from step 1 were placed into a vacuum chamber with a temperature of 250° C. for 2-3 minutes. Right after the removal of the samples from the chamber, contact angles were conducted immediately on the sample surfaces. In experiment step 2, a silicon substrate with a fresh CVD Cu deposit was used as a reference. Measurement results of contact angle from experiment step 1 are as following: BTA reference sample 60-65 degree, Sample A 18-25 degree, Sample B 17-25 degree, Sample C 25-30 degree, Sample D 27-32 degree, Sample E 20-26 degree. Measurement results from experiment step 2 are as following: Fresh Cu deposit sample 12-18 degree, Sample A 11-18 degree, Sample B 13-19 degrees. Sample C 24-29 degree, Sample D 26-32 degree, Sample E 14-21 degree. Therefore, Sample A, B, E will be able to replace BTA during process cleaning and to be removed during preconditioning of CVD processes.

The cleaning efficacy of the present invention to the substrate surface can be carried out using atomic force microscopy. The cleaning efficacy may be defined as a percentage of the total area of the substrate that is covered by the residues and/or contaminants. For example, the residues and/or contaminants on substrate can be registered as a range of pixels. Then atomic force microscope are programmed to perform a z-plane scan to identify topographic areas of interest above a certain height threshold and then calculate the area of the total surface covered by said areas of interest. The less area covered by said areas of interest post-cleaning, the more efficacious the processing composition. Accordingly, the cleaning efficiency can be evaluated according to the change in the number of residue and/or contaminant particles pre and post cleaning as following:

$$Cleaning Efficacy = \frac{\begin{matrix}Number of PreClean Particles - \\ Number of PostClean Particles\end{matrix}}{Number of PreClean Particles} \times 100 \%$$

Using the processing composition of the present invention, residues and/or contaminants on the substrate containing Cu interconnect can be partially or near completely removed. Cleaning efficacies on Cu interconnect containing substrates with preferred cleaning composition A, B and E are at least greater than 90%, preferably greater than 95%, and most preferably greater than 99%.

Processing composition of the present invention has a PH value greater than 7, preferably in the range of 8 to 14, more preferably in the range of 10 to 14, most preferably in the range of 12-14. The cleaning composition can be diluted with deionized water during application. Dilution ratio of the cleaning composition to water is from 1:0 to 1:500, preferably from 1:0 to 1:200.

1. A processing composition for removing residues and/or contaminants from Cu interconnect containing substrate, wherein the composition compromises at least one quaternary base, at least one organic amine, at least one surface modifier, at least one antioxidant, at least one complexing agent and balance water, wherein the substrate contains Cu and barrier metals as of Co, Ru, W, Mo, Rh, and alloys and nitride thereof, wherein the composition is compatible with the low-k dielectrics, Cu and barrier metals.

2. The composition of claim 1, wherein the quaternary base is preferably selected from tetramethylammonium hydroxide, (2-hydroxyethyl) trimethylammonium hydroxide, the organic amine preferably selected from monoethanolamine, the surface modifier preferably selected from 1,2,4-triazole, imidazole, pyrrole, pyrazole, the antioxidant preferably selected from ascorbic acid, the complexing agent preferably selected from (hydroxyethyl)ethylenediamine triacetic acid (HEDTA), nitrilotriacetic acid, wherein the processing composition possesses a PH value in a range of 8-14, more preferably in a range of 10-14, most preferably in a range of 12-14.

3. The composition of claim 1, wherein a preferred composition contains a combination of 0.01 wt % to 15 wt % tetramethylammonium hydroxide, 0.01 wt % to 10 wt % monoethanolamine, 0.01 wt % to 8 wt % 1,2,4-triazole, 0.001 wt % to 6 wt % ascorbic acid, 0.0001 wt % to 4 wt % (hydroxyethyl)ethylenediamine triacetic acid (HEDTA), and balance water, wherein a preferred composition contains a combination of 0.01 wt % to 15 wt % (2-hydroxyethyl) trimethylammonium hydroxide, 0.01 wt % to 10 wt % monoethanolamine, 0.01 wt % to 8 wt % 1,2,4-triazole, 0.001 wt % to 6 wt % ascorbic acid, 0.0001 wt % to 4 wt % nitrilotriacetic acid and balance water, wherein a preferred composition contains a combination of 0.01 wt % to 13 wt % (2-hydroxyethyl) trimethylammonium hydroxide, 0.01 wt % to 10 wt % monoethanolamine, 0.01 wt % to 5 wt % pyrazole, 0.001 wt % to 4 wt % ascorbic acid, 0.0001 wt % to 4 wt % (hydroxyethyl)ethylenediamine triacetic acid (HEDTA) and balance water.
